(19) United States
(12) Patent Application Publication
(10) Pub. No.: US 2006/0056267 A1
(43) Pub. Date: Mar. 16, 2006

(54) Driving unit and display apparatus having the same

(75) Inventors: Sung-Man Kim, Seoul (KR); Seong-Young Lee, Seoul (KR); Yeon-Kyu Moon, Seoul (KR); Yun-Hee Kwak, Seoul (KR); Jong-Woong Chang, Suwon-si (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/224,671

(22) Filed: Sep. 12, 2005

(30) Foreign Application Priority Data
Sep. 13, 2004 (KR) 2004-73127
Jun. 3, 2005 (KR) 2005-0047859

(51) Int. Cl. G11C 8/00; G11C 5/06

(52) U.S. Cl. 365/230.06; 365/63; 365/233

(57) ABSTRACT

In a driving unit (e.g., a gate driving unit) and a flat panel display apparatus having the driving unit, a circuit portion of the driving unit includes a plurality of driving stages cascade-connected to one another and outputs a (gate) driver signal (a plurality of gate-driving signals) based on a plurality of control signals. The line portion comprises a first signal line and a second signal line, each of which transmits control signals from the outside, and a first connection line connecting the first signal line to the driving stages, and a second connection line connecting the second signal line to the driving stages. The second signal line is positioned at a different (metallization) layer from the first signal line and the first and second connection lines. Therefore, malfunctioning of the driving unit caused by corrosion may be prevented.

### CROSS-REFERENCE TO RELATED APPLICATIONS

This application relies claims priority under 35 U.S.C. § 119 of Korean Patent Application No. 2004-73127 filed on Sep. 13, 2004, and of Korean Patent Application No. 2005-47859 filed on Jun. 3, 2005, the contents of which are herein incorporated by reference in their entireties.

### BACKGROUND OF THE INVENTION

1. Field of the Invention

The present invention relates to a driving unit and a display apparatus having the driving unit, and more particularly to a driving unit capable of preventing malfunction and a display apparatus having the driving unit.

2. Description of the Related Art

In general, a display apparatus (e.g., a liquid crystal display) comprises a display panel having a plurality of gate lines and a plurality of data lines, a gate driver disposed along one side of the display panel outputting a gate driver signal (a plurality of gate signals) to the gate lines, and a data driver disposed at the top of the display panel outputting a data driver signal (a plurality of data signals) to the data lines.

The gate and data drivers that have “built-in” structures are chips mounted on or integrated circuits formed upon a substrate of the display panel. When the display apparatus has the built-in gate driver, the size of the driver related circuits of the display apparatus is beneficially reduced.

The gate driver includes a shift register comprised of a plurality of driving stages, a plurality of signal lines transmitting various signals from the exterior to the gate driver and a plurality of connection lines electrically connecting the signal lines to the plurality of driving stages in the shift register. The signal lines are conventionally all formed on a layer different from that of the connection lines so that the signal lines are electrically connected to the connection lines through a plurality of contact electrodes.

The display panel includes an array substrate having a plurality of gate lines and a plurality of data lines formed thereon, a color filter substrate corresponding to the location of the array substrate, a liquid crystal layer situated between the array substrate and the color filter substrate, and a sealant uniting the array substrate with the color filter substrate. The color filter substrate includes a black matrix to block the light that passes through incontrollable portions of the liquid crystal layer. In general, the black matrix includes a metal material such as chrome (Cr) having an optical density of 3.5 or an organic material such as carbon (C).

In the display panel structure with the built-in gate driver, parasitic capacitance is formed between the gate driver and a common electrode of the color filter substrate formed on the black matrix. Such parasitic capacitance may induce a malfunction of the gate driver.

Recently, the sealant has been interposed between a gate driver and the common electrode so as to reduce the parasitic capacitance.

However, in the display panel structure with the built-in gate driver, the common electrode corresponding to the gate driver is formed on the black matrix. When the common electrode is electrically shorted to the gate driver having a lower electric potential than the common electrode, the black matrix including chrome (Cr) is corroded by the electric potential difference between the common electrode and the gate driver. Particularly, when the sealant is misaligned between the array substrate and the color filter substrate, the sealant is not interposed between the common electrode and the gate driver so that the black matrix may be corroded. Also, when the sealant is interposed between the common electrode and the gate driver, the gate driver may be electrically shorted to the common electrode due to a high permeability of the sealant. Therefore, malfunctioning of the gate driver may not be avoided when using the sealant.

### SUMMARY OF THE INVENTION

An embodiment of the present invention provides a driving unit capable of preventing malfunction. Another embodiment of the present invention provides a display apparatus having the above-mentioned driving unit.

In one aspect of the invention, the driving unit comprises a circuit part and a line part. The circuit part includes a plurality of driving stages to output a driver signal (e.g., a plurality of gate signals) based on a plurality of control signals. Each of the driving stages is cascade-connected to one another and outputs a gate (driving) signal.

The line part includes a first signal line, a second signal line, a first connection line electrically connecting the first signal line to the driving stages, and a second connection line electrically connecting the second signal line to the driving stages. Each of the first and the second signal lines transmits the control signals from the exterior to the driving unit. The first signal line, and the first and second connection lines are at (e.g., formed in) a different (metallization) layer from the second signal line.

In another aspect of the invention, a display apparatus using a plurality of gate signals (e.g., the gate driver signal) and a plurality of data signals (e.g., the data driver signal) to display an image comprises: a data driver for generating the data signals to be applied to the display panel, and a gate driver for generating the gate signals to be applied to the display panel.

The gate driver comprises a circuit part and a line part. The circuit part includes a plurality of (gate) driving stages and outputs a gate driver signal (the plurality of gate (driving) signals) based on a plurality of control signals. Each of the driving stages is cascade-connected to one another and outputs one of the gate (driving) signals.

The line part includes a first signal line, a second signal line, a first connection line electrically connecting the first signal line to the driving stages, and a second connection line electrically connecting the second signal line to the driving stages. Each of the first and second signal lines transmits the control signals from (the exterior) to the driving units. The first signal line, and the first and second connection lines are at (formed in) a different (metallization) layer from the second signal line.

In still another aspect of the invention, a display apparatus includes an array substrate and an opposite substrate.

The array substrate includes a first substrate, a driver and a pixel array. The first substrate is divided into a display area and a peripheral area adjacent to the display area. The driver is formed upon the first substrate corresponding to the peripheral area. The pixel array is formed on the first substrate corresponding to the display area. The driver outputs a driver signal, and the pixel array receives the driver signal from the driver.

The opposite substrate includes a second substrate facing the first substrate and a black matrix is formed upon the second substrate to block light. The black matrix has an opening formed in the peripheral area.

According to an aspect of the present invention, the first signal line is spaced apart from the circuit part, and is at (formed in) the same (metallization) layer as the first and second connection lines and is integrally formed with the first connection line corresponding thereto. Therefore, a contact electrode electrically connecting the first signal line to the first connection line that would have otherwise been necessary, may be omitted to prevent malfunction of driving unit caused by corrosion of the connection line.

### BRIEF DESCRIPTION OF THE DRAWINGS

The above and other features of the present invention will become readily apparent to persons skilled in the art by reference to the following detailed description when considered in conjunction with the accompanying drawings. It should be understood that the exemplary embodiments of the present invention described below may be varied and modified in many different ways without departing from the invention's principles disclosed herein, and the scope of the present invention is therefore not limited to these particular following embodiments. Rather, these embodiments are provided to convey the concept of the invention to those skilled in the art by way of example and not of limitation.

Hereinafter, the present invention will be described in detail with reference to the accompanying drawings. In the drawings, like numerals denote like elements, and:

FIG. 1 is a block diagram showing a gate driver in accordance with an exemplary embodiment of the present invention;

FIG. 2 is a plan view showing a portion (I) of the gate driver of FIG. 1;

FIG. 3 is a cross-sectional view taken along a line II-II′, in the portion (I) of the gate driver 160 of FIG. 1, shown in FIG. 2;

FIG. 4 is a circuit diagram showing a first driving stage SRC₁ of the gate driver 160 of FIG. 1;

FIG. 5 is a plan view showing a display apparatus in accordance with another exemplary embodiment of the present invention;

FIG. 6 is a cross-sectional view of the display apparatus of FIG. 5 taken along a line III-III′;

FIG. 7 is an enlarged cross-sectional view of the array substrate 100 shown in FIG. 6;

FIG. 8 is a cross-sectional view showing an array substrate in accordance with another exemplary embodiment of the present invention;

FIG. 9 is a cross-sectional view showing a display apparatus in accordance with another exemplary embodiment of the present invention; and

FIG. 10 is a plan view showing of the array substrate in FIG. 9.

### DESCRIPTION OF EXEMPLARY EMBODIMENTS OF THE INVENTION

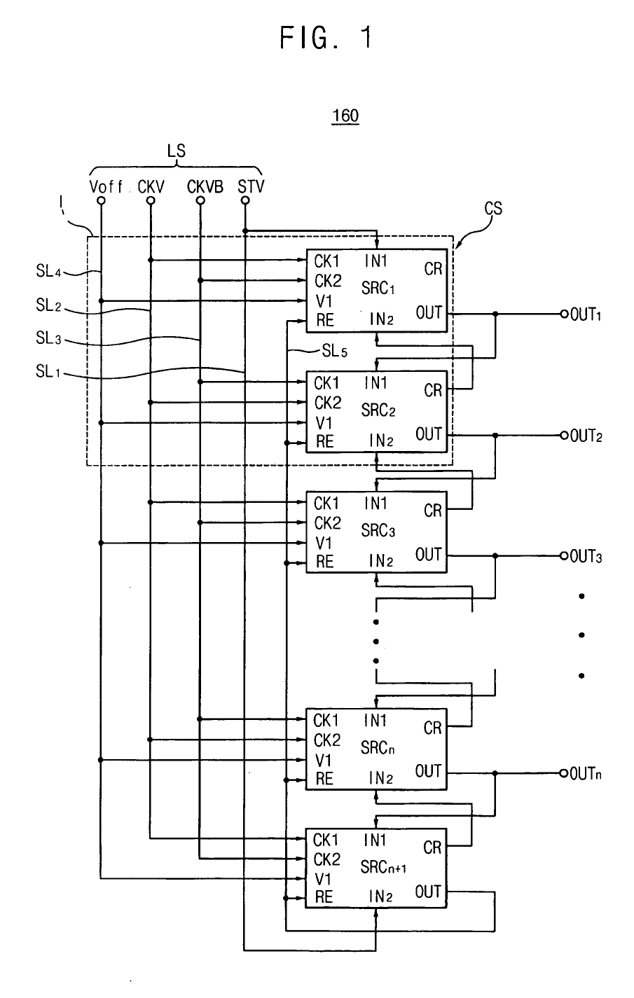

FIG. 1 is a block diagram showing a gate driver 160 in accordance with an exemplary embodiment of the present invention. Referring to FIG. 1, the gate driver 160 includes a circuit portion CS and a line portion LS adjacent to the circuit portion CS.

The circuit portion CS includes first to last (1^{st} to (n+1)-th, denoted by subscripts) driving stages SRC₁ to SRCₙ₊₁ that are cascade-connected to one another, to output a first to an n-th gate signals OUT₁ to OUTₙ in sequence, wherein ‘n’ is an even number.

Each of the first to (n+1)-th driving stages SRC₁ to SRCₙ₊₁ includes a first clock terminal CK1, a second clock terminal CK2, a first input terminal IN1, a second input terminal IN2, a turn off (ground)voltage terminal V1, a reset terminal RE, a carry terminal CR and an output terminal OUT.

A first clock signal CKV is applied to the first clock terminals CK1 of odd-numbered driving stages SRC₁, SRC₃, . . . , SRCₙ₊₁. A second clock signal CKVB having a different (e.g., opposite) phase from the first clock signal CKV is applied to the first clock terminals CK1 of even-numbered driving stages SRC₂, . . . , SRCₙ. In addition, the second clock signal CKVB is applied to the second clock terminals CK2 of the odd-numbered driving stages SRC₁, SRC₃, . . . . SRCₙ₊₁ and the second clock signal CKV is applied to the second clock terminals CK2 of the even-numbered driving stages SRC₂, . . . SRCₙ.

A start signal STV or a gate signal from a previous driving stage is applied to a first input terminal IN1 of each of the first to (n+1)-th driving stages SRC₁ to SRCₙ₊₁. The start signal STV is applied to the first input terminal IN1 of the first driving stage SRC₁ so as to initiate the operation of the circuit portion CS. The start signal STV is also applied to the second input terminal IN2 of the last (n+1)-th driving stages SRCₙ₊₁.

A next carry signal from the carry terminal CR of the next driving stage is applied to the second input terminal IN2 of each of the first n among the n+1 driving stages SRC₁ to SRCₙ. The last (n+1)-th driving stage SRCₙ₊₁ is a dummy driving stage provided to apply a next carry signal to the second input terminal IN2 of the n-th driving stage SRCₙ. The next carry signal is not applied to the second input terminal IN2 of the (n+1)-th driving stage SRCₙ₊₁, rather the start signal STV is applied to the second input terminal IN2 of the (n+1)-th driving stage SRCₙ₊₁.

A turn off (ground) voltage Voff is applied to the turn off (ground) voltage terminal V1 of each of the first to (n+1)-th driving stages SRC₁ to SRCₙ₊₁. The (n+1)-th gate signal outputted from output terminal OUT of the (n+1)-th driving stage SRCₙ₊₁ is applied as a reset signal to the reset terminal RE of each of the first to (n+1)-th driving stages SRC₁ to SRCₙ₊₁.

The carry signals outputted from the carry terminals CR of the second (subscript 2 denotes 2^{nd}) to last (n+1)-th driving stages SRC₂ to SRCₙ₊₁ are applied to the second input terminals IN2 of the previous driving stages. Also, the first to n-th gate signals OUT₁ to OUTₙ outputted from the output terminals OUT of the first (subscript 1 denotes 1^{st}) to n-th driving stages SRC₁ to SRCₙ are applied to the first input terminal IN1 of the next driving stages.

The line portion LS includes a start signal line SL₁, a first clock line SL₂, a second clock line SL₃, a turn off (ground) voltage line SL₄ and a reset line SL₅ that are substantially parallel with one another.

The start signal line SL, applies (or transmits) the start signal STV (e.g., from an previous driving stage) to the gate driver 160 at the first input terminal IN1 of the first (1^{st}) driving stage SRC₁ and at the second input terminal IN2 of the last (n+1)-th driving stage SRCₙ₊₁.

The first clock line SL₂ transmits the first clock signal CKV from the exterior to the gate driver 160, and the second clock line SL₃ transmits the second clock signal CKVB from the exterior to the gate driver 160. Also, the turn off (ground) voltage line SL₄ transmits the turn off (ground) voltage Voff from the exterior to the gate driver 160. The reset line SL₅ applies the (n+1)-th gate signal outputted from the output terminal OUT of the last (n+1)-th driving stage SRCₙ₊₁ to the reset terminals RE of the first to the last (n+1)-th driving stages SRC₁ to SRCₙ₊₁.

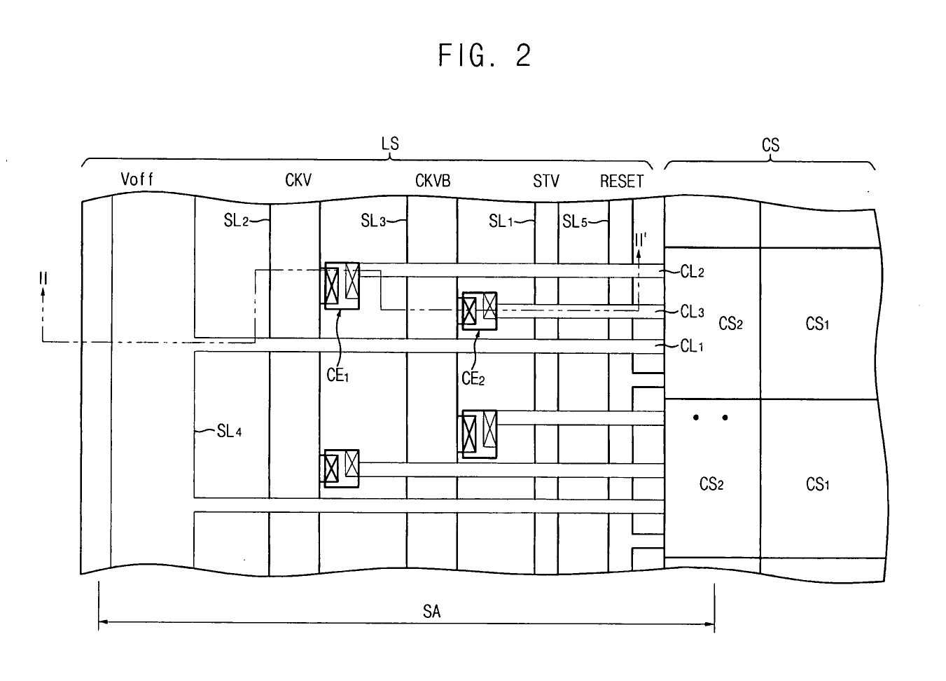

FIG. 2 is a plan view of a portion (I) of the gate driver 160 of FIG. 1.

Referring to FIG. 2, the line portion LS further comprises a plurality of (horizontal) connection lines for connecting each of signal lines SL₄, SL₂, SL₃ to each of the driving stages SRC₁, through SRCₙ₊₁: a first connection line CL₁, a second connection line CL₂ and a third connection line CL₃ (see FIG. 2), respectively.

The first connection line CL₁ electrically connects the turn off (ground) voltage line SL₄ to the turn off (ground) voltage terminals V1 of the first to (n+1)-th driving stages SRC₁ to SRₙ₊₁ of the circuit portion CS. The second connection line CL₂ electrically connects the first clock line (CKV) SL₂ to the first clock terminals CK1 of the odd-numbered driving stages SRC₁, SRC₃, . . . SRCₙ₊₁ and to the second clock terminals CK2 of the even-numbered driving stages SRC₂, SRC₄ . . . , SRCₙ. The third connection line CL₃ electrically connects the second clock line (CKVB) SL₃ to the first clock terminals CK1 of the even-numbered driving stages SRC₂, SRC₄ . . . , SRCₙ and the second clock terminals CK2 of the odd-numbered driving stages SRC₁, SRC₃, . . . SRCₙ₊₁.

Referring to FIG. 2, each of the first to n-th driving stages SRC₁ to SRCₙ of the circuit portion CS includes a first circuit part CS₁ electrically connected to an output terminal OUT to control an output of the first to n-th gate signals, and a second circuit part CS₂ for controlling the first circuit part CS₁.

The line portion LS includes the start signal line SL₁, the first clock line SL₂, the second clock line SL₃, the turn off (ground) voltage line SL₄ and the reset line SL₅. The line portion LS further comprises a first connection line CL₁, a second connection line CL₂ and a third connection line CL₃.

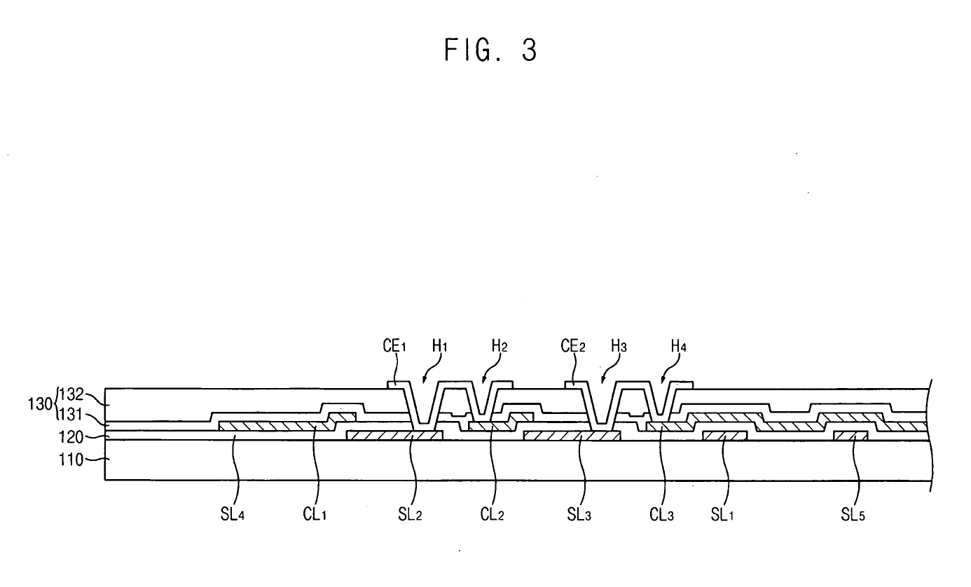

FIG. 3 is a cross-sectional view taken along a line II-II′ in the portion (I) of the gate driver 160 of FIG. 1, shown in FIG. 2.

As shown in FIG. 3, the start signal line SL₁, the first clock line SL₂, the second clock line SL₃, and the reset line SL₅ are formed in a first metal layer and are positioned upon a first plate 110.

A gate insulation film 120 is deposited upon the first plate 110 comprising (forming) the start signal line SL₁, the first clock line SL₂, the second clock line SL₃, and the reset line SL₅.

The turn off (ground) voltage line SL₄, and the first, second and third connection lines CL₁, CL₂ and CL₃ are formed in a second metal layer. The turn off (ground) voltage line SL₄, and the first, second and third connection lines CL₁, CL₂ and CL₃ are deposited upon the gate insulation film 120. When the first, second and third connection lines CL₁, CL₂ and CL₃ are at a different (metallization) layer from the start signal line SL₁, the first clock line SL₂, the second clock line SL₃, and the reset line SL₅, then the first, second and third connection lines CL₁, CL₂ and CL₃ are electrically insulated from the start signal line SL₁, the first clock line SL₂, the second clock line SL₃, and the reset line SL₅.

The turn off (ground) voltage line SL₄ and the first connection line CL₁ are deposited upon the gate insulation film 120 so that the turn off (ground) voltage line SL₄ and the first connection line CL, are simultaneously patterned, deposited and integrally formed with each other. Therefore, a contact electrode that would otherwise electrically connect the turn off (ground) voltage line SL₄ to the first connection line CL₁ may be and is omitted.

A passivation film 130 is formed upon the gate insulation film 120 upon which the turn off (ground) voltage line SL₄ and the first, second and third connection lines CL₁, CL₂ and CL₃ are formed. The passivation film 130 comprises an inorganic insulation film 131 and an organic insulation film 132.

A first contact hole H₁ is formed through the passivation film 130 and through the gate insulation film 120 to the first clock line SL₂. And a second contact hole H₂ is formed through the passivation film 130 to the second connection line CL₂. The first and second contact holes H₁ and H₂ partially expose the first clock line SL₂ and the second connection line CL₂. Therefore, the first contact electrode CE, (formed within and between the first and second contact holes H₁ and H₂) electrically connects the first clock line SL₂ and the second connection line CL₂ that are partially exposed through the first and second contact holes H₁ and H₂, respectively. Also, a third contact hole H₃ is formed through the passivation film 130 and the gate insulation film 120 to the second clock line SL₃. A fourth contact hole H₄ is formed through the passivation film 130 to the third connection line CL₃. The third and fourth contact holes H₃ and H₄ partially expose the second clock line SL₃ and the third connection line CL₃, respectively. Therefore, the second contact electrode CE₂ (formed within and between the third and fourth contact holes H₃ and H₄) electrically connects the second clock line SL₃ and the third connection line CL₃ that are partially exposed through the third and fourth contact holes H₃ and H₄. Each of the first and second contact electrodes CE, and CE₂ may include a conductive material such as indium tin oxide (ITO) or indium zinc oxide (IZO).

The first clock line SL₂ and the second connection line CL₂ are on a layer different from each other and are electrically connected to each other through the first contact electrode CE₁ (see also FIG. 2). The second clock line SL₃ and the third connection line CL₃ are on a layer different from each other and are electrically connected to each other through the second contact electrode CE₂ (see also FIG. 2).

The first, second and third connection lines CL₁, CL₂ and CL₃ are on the (metallization) layer different from the start signal line SL1, the first clock line SL₂, the second clock line SL₃ and the reset line SL₅ so that each of the first, second and third connection lines CL₁, CL₂ and CL₃ is electrically insulated from the start signal line SL₁, the first clock line SL₂, the second clock line SL₃ and the reset line SL₅.

The turn off (ground) voltage line SL₄ is close to one side of the first plate 110. Thus, the turn off (ground) voltage line SL₄ is closer to the one side of the first plate 110 than are the start signal line SL₁, the first clock line SL₂, the second clock line SL₃ and the reset line SL₅ so that the turn off (ground) voltage line SL₄ does not overlapped upon the second and third connection lines CL₂ and CL₃.

Therefore, the turn off (ground) voltage line SL₄ may be deposited in the same layer as the first, second and third connection lines CL₁, CL₂ and CL₃. In this exemplary embodiment of the invention, the contact electrode that would otherwise be provided to electrically connect the turn off (ground) voltage line SL₄ to the first connection line CL₁ may be and is omitted so that the number of contact electrodes formed in the gate driver 160 is decreased. In addition, the line resistance between the turn off (ground) voltage line SL₄ and the first connection line CL₁ is decreased, and the corrosion of the gate driver 160 caused by the omitted contact electrode may be prevented.

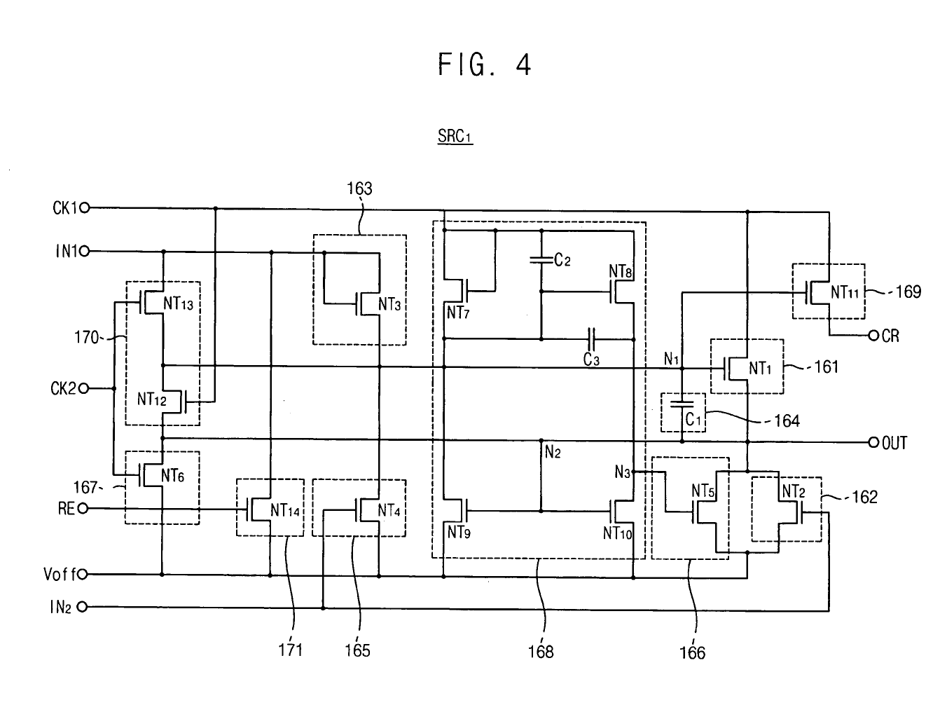

FIG. 4 is a circuit diagram showing the first driving stage SRC₁ of the gate driver 160 of FIG. 1. The first driving stage SRC₁ is substantially the same as the second to (n+1)-th driving stages SRC₂ to SRCₙ₊₁ so that any further explanation concerning the second to (n+1)-th driving stages SRC₂ to SRCₙ₊₁ may be omitted.

Referring to FIG. 4 and FIG. 1, the first driving stage SRC₁ comprises a pull-up part 161 and a pull-down part 162, a pull-up driver part (including a first charge part 163, and a first discharge part 165, and a buffer part 164), a holding part 166, a second discharge part 167, a switching part 168, a carry part 169, a ripple preventing part 170 and a reset part 171.

The pull-up part 161 pulls up (up to the first clock signal CKV) the gate (driving) signal to be outputted from the output terminal OUT (shown in FIG. 1). The pull-down part 162 pulls down (down to the turn-off (ground) voltage Voff) the gate signal based on the next carry signal from the next driving stage (e.g., second driving stage SRC₂) (as shown in FIG. 1).

The pull-up part 161 includes a first (N-FET) transistor NT₁. The first transistor NT₁ has a gate electrode that is electrically connected to a first node N₁, a drain electrode that is electrically connected to a first clock terminal CK1, and a source electrode that is electrically connected to the output terminal OUT. The pull-down part 162 includes a second (N-FET) transistor NT₂. The second transistor NT₂ has a gate electrode that is electrically connected to the second input terminal IN2, a drain electrode that is electrically connected to the output terminal OUT, and a source electrode. The turn off (ground) voltage Voff is applied to the source electrode of the second transistor NT₂.

The first driving stage SRC₁ further comprises a pull-up driver part (comprised of a charge part 163, and a first discharge part 165, and a buffer part 164). The pull-up driver part turns on the pull-up part 161 based on the start signal (STV via IN1) and turns off the pull-up part 161 based on the next carry signal from the next (e.g., second) driving stage SRC₂. The pull-up driver part includes, a first charge part 163, and a first discharge part 165, and a buffer part 164.

The charge part 163 has a third transistor NT₃. The third transistor NT₃ has a gate electrode that is electrically connected to the first electrode that is also electrically connected to the first input terminal IN1, a drain electrode that is electrically connected to the first input terminal IN1, and a source electrode that is connected to a first node N₁. The buffer part 164 includes a first capacitor C₁. The first capacitor C, has a first electrode that is electrically connected to the first node N₁, and a second electrode that is electrically connected to a second node N₂ (OUT). The discharge part 165 includes a fourth transistor NT₄. The fourth transistor NT₄ has a gate electrode that is electrically connected to the second input terminal IN2, a drain electrode that is electrically connected to the first node N₁, and a source electrode. The turn off (ground) voltage Voff is applied to the source electrode of the fourth transistor NT₄.

When the third transistor NT₃ is turned on (e.g., based on the start signal STV), the first capacitor C₁ is charged by an electric charge formed by accumulating charge (e.g., from the start signal STV). When the electric charge stored in the first capacitor C₁ has a voltage greater than a threshold voltage of the first transistor NT₁, then the first transistor NT₁ is turned on (bootstrapped) to output (pass) the (first) clock signal CKV having a high level to the output terminal OUT. When the fourth transistor NT₄ (of the discharge part 165) is turned on based on the next carry signal, the electric charge stored in the first capacitor C, is discharged to the turn off (ground) voltage Voff.

The first driving stage SRC₁ further includes a holding part 166, a second discharge part 167 and a switching part 168. The holding part 166 holds down the level of the gate signal to the turn off (ground) voltage Voff. The switching part 168 controls the operation of the holding part 166. The second discharge part 167 discharges the gate signal (at node N2 and OFF) to the turn off (ground) voltage based on the second clock signal CKVB.

The holding part 166 includes a fifth transistor NT₅. The fifth transistor NT₅ has a gate electrode that is connected to a third node N₃, a drain electrode that is connected to the second node N₂ (OUT), and a source electrode. The turn off (ground) voltage Voff is applied to the source electrode of the fifth transistor NT₅. The second discharge part 167 includes a sixth transistor NT₆. The sixth transistor NT₆ has a gate electrode that is connected to a second clock terminal CK2, a drain electrode that is connected to the second node N₂, and a source electrode. The turn off (ground) voltage Voff is applied to the source electrode of the sixth transistor NT₆.

The switching part 168 includes a seventh transistor NT₇, an eighth transistor NT₈, a ninth transistor NT₉, a tenth transistor NT₁₀, a second capacitor C₂, and a third capacitor C₃.

The seventh transistor NT₇ has a gate electrode that is electrically connected to the first clock terminal CK1, a drain electrode that is electrically connected to the first clock terminal CK1, and a source electrode that is connected to the third node N₃. The eighth transistor NT₈ has a drain electrode that is electrically connected to the first clock terminal CK1, a gate electrode that is electrically connected to the first clock terminal CK1 through the second capacitor C₂, and a source electrode that is electrically connected to the third node N₃. The third capacitor C₃ is connected between the gate and source electrodes of the eighth transistor NT₈.

The ninth transistor NT₉ has a gate electrode that is electrically connected to the second node N₂ (OUT), a drain electrode that is electrically connected to the source electrode of the seventh transistor NT₇, and a source electrode. The turn off (ground) voltage Voff is applied to the source electrode of the ninth transistor NT₉. The tenth transistor NT₁₀ has a gate electrode that is electrically connected to the second node N₂ (OUT), a drain electrode that is electrically connected to the third node N₃, and a source electrode. The turn off (ground) voltage is applied to the source electrode of the tenth transistor NT₁₀.

When the first clock signal CKV (via CK1) is outputted (passed) to the output terminal OUT and the seventh and eighth transistors NT₇ and NT₈ are turned on by the first clock signal CKV, a signal in a high state is applied to the second node N₂ (OUT). When the signal in a high state is applied to the second node N₂ (OUT), the ninth and tenth transistors NT₉ and NT₁₀ are turned on, and the voltages outputted from the seventh and eighth transistors NT₇ and NT₈ are discharged to the turn off (ground) voltage Voff through the ninth and tenth transistors NT₉ and NT₁₀. Therefore, the third node N₃ is maintained as a low level so that the fifth transistor NT₅ is turned off.

When the gate signal (second node N₂, OUT) is discharged to the turn off (ground) voltage Voff by the next carry signal, the level of the second node N₂ gradually decreases to a low level. Therefore, the ninth and tenth transistors NT₉ and NT₁₀ are turned off, and the level of the signal applied to the third node N₃ gradually increases by the voltages outputted from the seventh and eighth transistors NT₇ and NT₈. When the level of the signal applied to the third node N₃ increases, the fifth transistor NT₅ is turned on and the level of the signal applied to the second node N₂ (OUT) rapidly decreases to the turn off (ground) voltage Voff by the turned-on fifth transistor NT₅.

When the sixth transistor NT6 is turned on by the second clock signal CKVB applied to the second clock terminal CK2, the level of the signal applied to the second node N₂ (OUT) is discharged to the turn off (ground) voltage Voff.

The carry part 169 includes an eleventh transistor NT₁₁. The eleventh transistor NT₁₁ has a gate electrode that is electrically connected to the first node N₁, a drain electrode that is electrically connected to the first clock terminal CK1 (e.g., CKV), and a source electrode that is connected to the carry terminal CR. The eleventh transistor NT₁₁ is turned on when the level of the first node N₁ increases, and outputs the first clock signal CKV that is applied to the drain electrode of the eleventh transistor NT₁₁ as the carry signal to the carry terminal CR. Thus first clock signal CKV is outputted from the carry terminal CR (and the output terminals OUT) of the odd-numbered driving stages SRC₁, SRC₃, . . . , SRCₙ₊₁, and the second clock signal CKVB is outputted from the carry terminals CR (and the output terminals OUT) of the even-numbered driving stages SRC₂, . . . , SRCₙ.

The ripple preventing part 170 includes a twelfth transistor NT₁₂ and a thirteenth transistor NT₁₃. The twelfth transistor NT₁₂ has a gate electrode that is electrically connected to the first clock terminal CK1 (e.g., CKV), a drain electrode that is electrically connected to the source electrode of the thirteenth transistor NT₁₃, and a source electrode that is electrically connected to the second node N₂ (OUT). The thirteenth transistor NT₁₃ has a gate electrode that is electrically connected to the second clock terminal CK2, a drain electrode that is electrically connected to the first input terminal IN1, and a source electrode that is electrically connected to the drain electrode of the eleventh transistor NT₁₁.

When the first gate signal (second node N₂, OUT) is discharged to the turn off (ground) voltage Voff, the ripple preventing part 170 prevents the first gate signal from being rippled by the first and second clock signals CK1 and CK2.

The reset part 171 includes a fourteenth transistor NT14. The fourteenth transistor NT₁₄ has a gate electrode that is electrically connected to a reset terminal RE, a drain electrode that is electrically connected to the first input terminal IN1, and a source electrode. The turn off (ground) voltage Voff is applied to the source electrode of the fourteenth transistor NT₁₄. When the (n+1)-th gate signal is applied to the reset terminal RE (of the (n+1)-th driving stage SRCₙ₊₁), the fourteenth transistor NT₁₄ is turned on and discharges the signal applied to the source electrode of the fourteenth transistor NT₁₄ through the first input terminal IN1 to the turn off (ground) voltage Voff. Therefore, the third transistor NT₃ may not be turned-on by the signal applied through the first input terminal IN1.

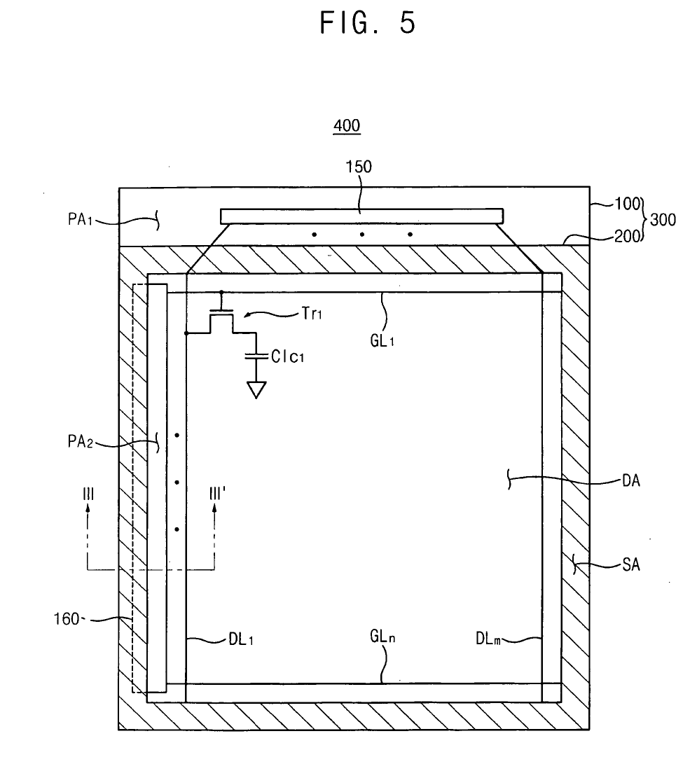

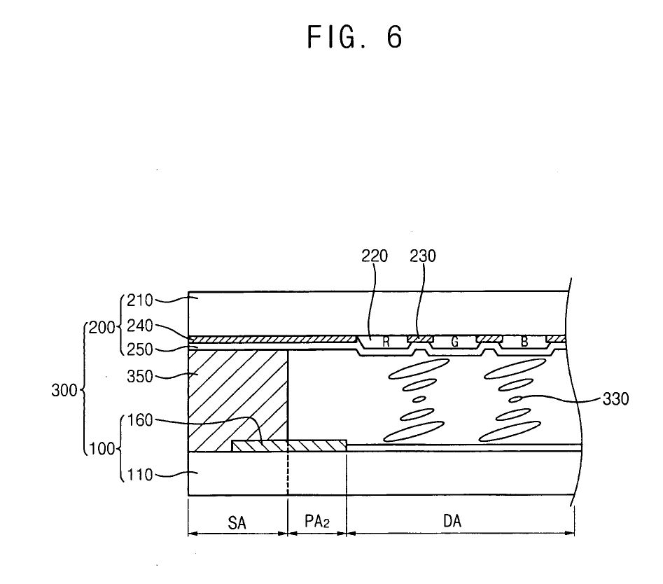

FIG. 5 is a plan view showing a display apparatus in accordance with another exemplary embodiment of the present invention. FIG. 6 is a cross-sectional view taken along a line III-III′ shown in FIG. 5.

Referring to FIGS. 5 and 6, a display apparatus 400 includes a display panel 300, a data driver 150 and a gate driver 160. The display panel 300 displays an image based on a first (data) driver signal and a second (gate) driver signal. The data driver 150 and the gate driver 160 output the first and second driver signals, respectively.

The display panel 300 comprises an array substrate 100, a color filter substrate 200 facing the array substrate 100, a liquid crystal layer 330 (see FIG. 6) between the array substrate 100 and the color filter substrate 200, and a sealant 350 uniting the array substrate 100 with the color filter substrate 200.

The display panel 300 includes a display area DA displaying the image, a seal line area SA surrounding the display area DA, a first peripheral area PA₁ adjacent to the seal line area SA and a second peripheral area PA₂. The second peripheral area PA₂ is disposed between the display area DA and a portion of the seal line area SA.

A first to an n-th gate lines GL₁ to GLₙ and a first to an m-th data lines DL₁ to DLₘ are formed on a first plate 110 of the array substrate 100 within to the bounds of the display area DA. The first to n-th gate lines GL₁ to GLₙ cross the first to m-th data lines DL₁ to DLₘ. The first to n-th gate lines GL₁ to GLₙ are electrically insulated from the first to m-th data lines DL₁ to DLₘ. Also, a plurality of thin film transistors (TFTs, e.g., Tᵣ₁) and a plurality of liquid crystal capacitors (Cl_{C1}) are formed on the first plate 110 within the display area DA.

For example, a gate electrode of a first thin film transistor Tr₁ among the plurality (e.g., 3×n×m) of thin film transistors is electrically connected to the first gate line GL₁. A source electrode of the first thin film transistor Tr₁ is electrically connected to the first data line DL₁. A drain electrode of the first thin film transistor Tr₁ is electrically connected to a first liquid crystal capacitor Cl_{C1} among the plurality (e.g., 3×n×m) of liquid crystal capacitors.

The color filter substrate 200 corresponding to (within) the display area DA includes a color filter layer 220 abutting on a second plate 210 and including a red color filter portion R, a green color filter portion G and a blue color filter portion B, and a first black matrix 230. The first black matrix 230 is disposed between two adjacent color filter portions among the red, green and blue filter portions R, G, and B. Also, a second black matrix 240 is disposed on the second plate 210 corresponding to (within) the seal line area SA. A common electrode 250 is formed abutting on the second plate 210 and the color filter layer 220, and the first and second black matrixes 230 and 240.

The first plate 110 of the array substrate 100 protrudes beyond the second plate 210 and the color filter substrate 200 at the first peripheral area PA₁. The data driver 150 (see FIG. 5) having a chip-shape is disposed upon the first platello corresponding to (within) the first peripheral area PA₁. The data driver 150 is electrically connected to the first to n-th data lines DL₁ to DLₙ in the display area DA. The first driver signal outputted from the data driver 150 includes first to m-th data signals, and the first to m-th data signals are applied to the first to m-th data lines DL₁ to DLₘ, respectively.

The gate driver 160 is simultaneously formed from the same (metallization) layers as the thin film transistors, in the second peripheral area PA₂ and the seal line area SA adjacent to the second peripheral area PA₂. The gate driver 160 is electrically connected to the first to n-th gate lines GL₁ to GLₙ on the display area DA. The second driver signal outputted from the gate driver 160 includes first to n-th gate signals OUT₁ to OUTₙ (shown in FIG. 1), and the first to n-th gate signals are applied to the first to n-th gate lines GL₁ to GLₙ, respectively.

The liquid crystal layer 330 is disposed between the color filter substrate 200 and the array substrate 100 corresponding to (within) the display area DA and the second peripheral area PA₂. The sealant 350 is formed in the seal line area SA to unite the array substrate 100 with the color filter substrate 200.

The sealant 350 partially covers the gate driver 160 within the seal line area SA. Therefore, the sealant 350 prevents a short-circuit between the common electrode 250 (which may be formed by conductive particles) and the gate driver 160.

Also, a parasitic capacitance generated between the common electrode 250 and the gate driver 160 decreases due to the sealant 350 having a dielectric constant less than the liquid crystal layer 330 between the common electrode 250 and the gate driver 160. Therefore, malfunctioning of the gate driver 160 may be prevented.

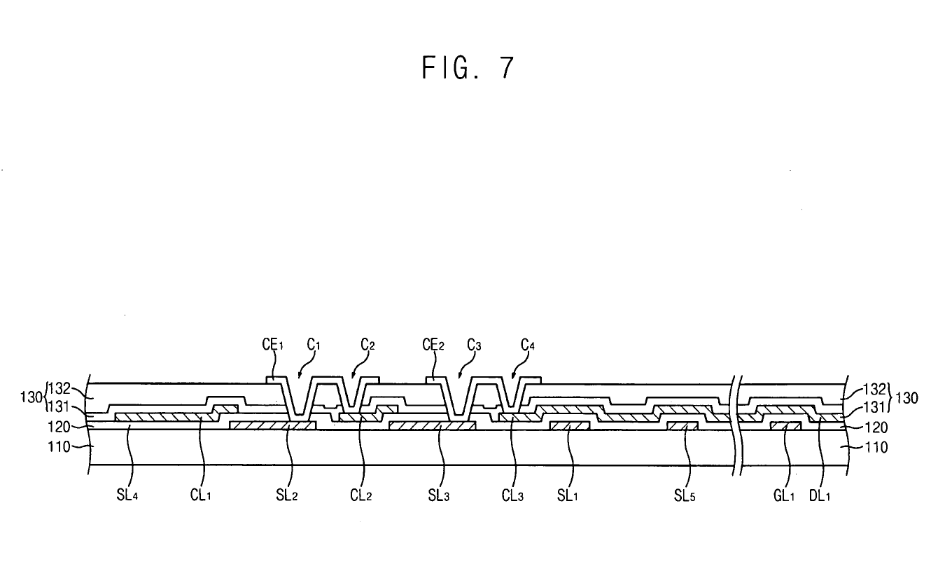

FIG. 7 is an enlarged cross-sectional view of the array substrate 100 shown in FIG. 6.

Referring to FIG. 7, a start signal line SL1, a first clock line SL₂, a second clock line SL₃, a reset line SL₅ and a first gate line GL, are formed in the same metallization layer (e.g., a first metal layer). The start signal line SL₁, the first clock line SL₂, the second clock line SL₃, the reset line SL₅ and the first gate line GL1 are deposited upon the first plate 110.

The first metal layer may, for example, have a mono-layered structure including an aluminum-based metal, a silver-based metal, a copper-based metal, a molybdenum-based metal, chromium, tantalum or titanium.

Alternatively, the first metal layer may have a double-layered structure consisting of a lower sub-layer and an sub-upper layer. The upper sub-layer is upon the lower sub-layer, and has different physical properties from the lower sub-layer. The upper sub-layer includes a metal having a low resistivity, such as an aluminum-based metal, a silver-based metal, a copper-based metal, to reduce a signal delay or a voltage drop. The lower sub-layer may include a material having good step coverage with ITO and IZO, such as chromium, molybdenum, an alloy of molybdenum, tantalum or titanium, etc.

In one exemplary embodiment, the first metal layer having the double-layered structure may include an upper sub-layer consisting of aluminum neodymium and a lower sub-layer consisting of molybdenum tungsten.

A gate insulation film 120 is formed upon the first plate 110 and upon the start signal line SL₁, the first clock line SL₂, the second clock line SL₃, the reset line SL₅ and the first gate line GL₁.

The turn off (ground) voltage line SL₄, first, second and third connection lines CL₁, CL₂ and CL₃ and first data line DL₁ are formed in the same metallization layer (e.g., a second metal film) and are formed upon the gate insulation film 120. The second metal film (layer) may have a mono-layered structure consisting of chromium, or a triple-layered structure formed by laminating molybdenum tungsten, aluminum neodymium and molybdenum tungsten sub-layers, in sequence.

The first, second and third connection lines CL₁, CL₂ and CL₃ are in a different layer from the start signal line SL₁, the first clock line SL₂, the second clock line SL₃ and the reset line SL₅ and are separated by the gate insulation film 120. Therefore, the first, second and third connection lines CL₁, CL₂ and CL₃ are electrically insulated from the start signal line SL₁, the first clock line SL₂, the second clock line SL₃ and the reset line SL₅.

The turn off (ground) voltage line SL₄ and the first connection line CL₁ are deposited upon the gate insulation film 120. Therefore, the turn off (ground) voltage line SL₄ and the first connection line CL₁ may be simultaneously patterned on the gate insulation film 120 and integrally formed with each other. As a result, the contact electrode that would otherwise be provided to electrically connect the turn off (ground) voltage line SL₄ to the first connection line CL₁ may be omitted.

A passivation film 130 is formed upon the layer comprising the turn off (ground) voltage line SL₄ and the first, second and third connection lines CL₁, CL₂ and CL₃, and upon the gate insulation film 120. The passivation film 130 may include an inorganic insulation film 131 and an organic insulation film 132.

The first clock line SL₂ and the second connection line CL₂ that are at the different metallization layers from each other are electrically connected to each other through the first contact electrode CE₁. The second clock line SL₃ and the third connection line CL3 that are at the different layers from each other are electrically connected to each other through the second contact electrode CE₂. The turn off (ground) voltage line SL₄ and the first connection line CL₁ are at the same layer and are integrally formed with each other.

The first, second and third connection lines CL₁, CL₂ and CL₃ are at the different layer from the start signal line SL₁, the first clock line SL₂, the second clock line SL₃ and the reset line SL₅ so that each of the first, second and third connection lines CL₁, CL₂ and CL₃ may be electrically insulated from the portions of the start signal line SL₁, the first clock line SL₂, the second clock line SL₃ and the reset line SL₅ which are not electrically connected to the first, second and third connection lines CL₁, CL₂ and CL₃.

The turn off (ground) voltage line SL₄ is closer to one side of the first plate 110 than the start signal line SL₁, the first clock line SL₂, the second clock line SL₃ and the reset line SL₅ so that the turn off (ground) voltage line SL₄ may does not overlap the second and third connection lines CL₂ and CL₃. Therefore, the turn off (ground) voltage line SL₄ may be at the same layer as the first, second and third connection lines CL₁, CL₂ and CL₃. As a result, the number of contact electrodes formed in the gate driver 160 decreases, thereby line resistance, that may otherwise be increased by the contact electrode, may be decreased.

Additionally, when the sealant 350 (shown in FIG. 6) is misaligned with the array substrate 100, the turn off (ground) voltage line SL₄ may be partially exposed adjacent to the sealant 350. Although the turn off (ground) voltage line SL₄ is partially exposed adjacent to the sealant 350, the corrosion rate of the gate driver due to the contact electrode may be decreased, thereby preventing the malfunction of the gate driver 160.

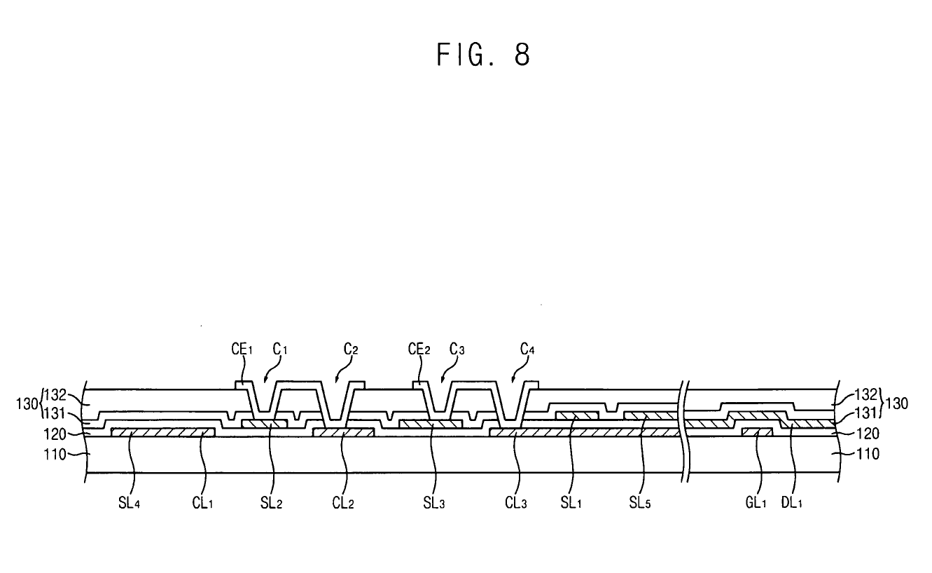

FIG. 8 is a cross-sectional view showing an array substrate 100 in accordance with another exemplary embodiment of the present invention.

Referring to FIG. 8, a turn off (ground) voltage line SL₄, a first connection line CL₁, a second connection CL₂, a third connection line CL₃ and a first gate line GL, are formed upon a first plate 110 of the array substrate 100. Each of the turn off (ground) voltage line SL₄, the first connection line CL₁, the second connection CL₂, the third connection line CL₃ and the first gate line GL₁ comprises (is formed in) a first metal layer.

A gate insulation film 120 is formed upon the first plate 110 and upon a first metal layer comprising the turn off (ground) voltage line SL₄, the first, second and third connection lines CL₁, CL₂ and CL₃ and the first gate line GL₁. A start signal line SL₁, a first clock line SL₂, a second clock line SL₃, a reset line SL₅ and a first data line DL₁ are deposited upon the gate insulation film 120 (in a second metallization layer).

A passivation film 130 is formed upon the gate insulation film 120 and upon the second metal layer comprising the start signal line SL₁, first and second clock lines SL₂ and SL₃, the reset line SL₅ and the first data line DL1.

The first clock line SL₂ and the second connection line CL₂ that are at different layers from each other but are electrically connected to each other through the first contact electrode CE₁. The second clock line SL₃ and the third connection line CL3 that are at the different layers from each other but are electrically connected to each other through the second contact electrode CE₂.

The turn off (ground) voltage line SL₄ and the first connection line CL, are at the same layer and are integrally formed with each other. Therefore, a contact electrode that would otherwise be provided for electrically connecting the turn off (ground) voltage line SL₄ and the first connection line CL, may be omitted so that the number of contact electrodes in the gate driver 160 may be reduced. Therefore, line resistance between the turn off (ground) voltage line SL₄ and the first connection line CL, may is decreased to prevent the corrosion of the gate driver 160 caused by the contact electrode.

In alternative embodiments of the invention, when one of the first clock line SL₂ and the second clock line SL₃ is closer to the side of the array substrate than the turn off (ground) voltage line SL₄, then that one of the first clock line SL₂ or the second clock line SL₃ may be formed in the same (metallization) layer as the first, second and third connection lines CL₁, CL₂ and CL₃. And, if one of the first clock line SL₂ or the second clock line SL₃ is integrally formed with a corresponding one of the second connection line CL₂ or the third connection line CL₃, then the corresponding one of the first contact electrode CE₁ or the second contact electrode CE₂ may be omitted to prevent corrosion of the gate driver 160 caused by the first contact electrode CE, or the second contact electrode CE₂.

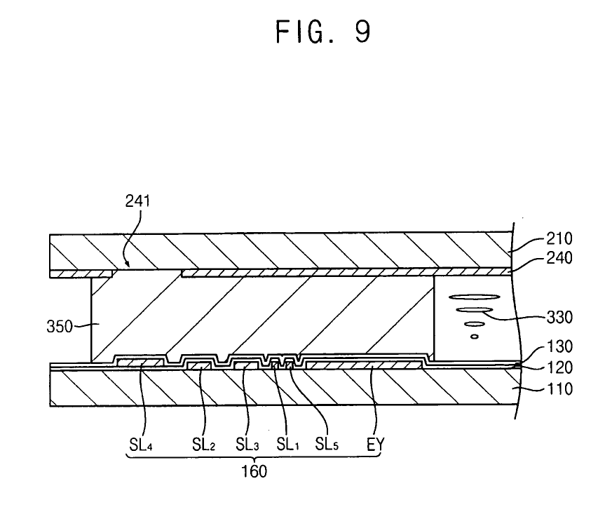

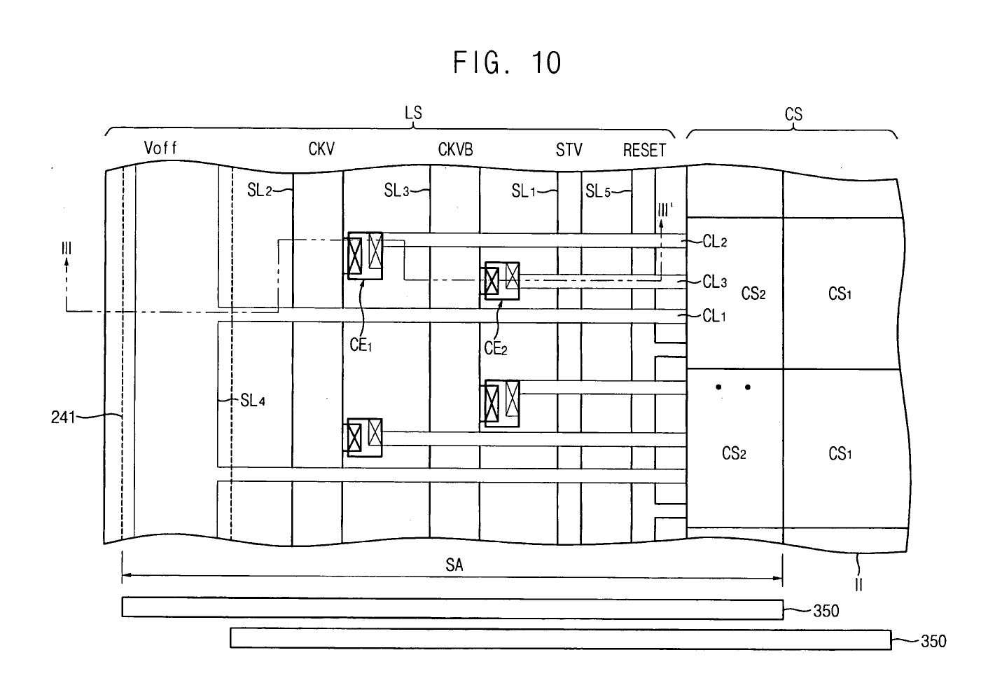

FIG. 9 is a cross-sectional view showing a display apparatus in accordance with another exemplary embodiment of the present invention. FIG. 10 is a plan view showing an array substrate in FIG. 9. In FIGS. 9 and 10, the same reference numerals denote the same elements in FIGS. 1 to 8, and thus any further repetitive descriptions of the same elements will be omitted.

Referring to FIGS. 9 and 10, the gate driver 160 includes a start signal line SL₁, first and second clock lines SL₂ and SL₃, a turn off (ground) voltage line SL₄, a reset line SL₅ and an electrode layer EY

The turn off (ground) voltage line SL₄ is formed from a first metal layer, and the start signal line SL₁, the first and second clock lines SL₂ and SL₃, the reset line SL₅ and the electrode layer EY are formed from a second metal layer (different from the first metal layer).

The first metal layer including the start signal line SL1, the first and second clock lines SL₂ and SL₃, the reset line SL₅ and the electrode layer EY is formed upon the first substrate 110. The gate insulating layer 120 is formed upon the first substrate 110 and upon the first metal layer to cover the start signal line SL₁, the first and second clock lines SL₂ and SL₃, the reset line SL₅ and the electrode layer EY. The turn off (ground) voltage line SL₄ is formed upon the gate insulating layer 120. Therefore, the turn off (ground) voltage line SL₄ is closer to a surface of the second substrate 210 than the start signal line SL₁, the first and second clock lines SL₂ and SL₃, the reset line SL₅ and the electrode layer EY.

The passivation layer 130 is formed upon the gate insulating layer 120 and upon the second metallization layer to cover the turn off (ground) voltage line SL₄. The passivation layer 130 may include an organic insulating layer and/or an inorganic insulating layer. In the present embodiment, the turn off (ground) voltage line SL₄ is covered by the passivation layer 130, but the start signal line SL₁, the first and second clock lines SL₂ and SL₃, the reset line SL₅ and the electrode layer EY are covered by the gate insulating layer 120 and the passivation layer 130.

An opening 241 is formed through the second black matrix 240 and corresponds with the position of the turn off (ground) voltage line SL₄. The opening 241 has a greater width than the turn off (ground) voltage line SL₄ or has substantially a same width as the turn off (ground) voltage line SL₄. The second black matrix 240 includes a metal material such as chrome(Cr).

When the common electrode 250 (referring to FIG. 6) is formed upon the second black matrix 240, the common electrode 250 corresponding to the location of the turn off (ground) voltage line SL₄ is formed upon the second substrate 210 exposed through the opening 241.

Thus, a short-circuit between the turn off (ground) voltage line SL₄ and the second black matrix 240 and a corrosion of the second black matrix may be prevented. Also, when the common electrode 250 is formed on the second black matrix 240, a corrosion of the second black matrix may be prevented because the second black matrix 240 is partially removed in an area corresponding to the turn off (ground) voltage line SL₄.

Although the sealant 350 may be misaligned between the array substrate 100 and the color filter substrate 200, the opening 241 may prevent a short-circuit between the second black matrix 240 and the turn off (ground) voltage line SL₄.

Accordingly, in the driving unit and the display apparatus having the driving unit array, the turn off (ground) voltage line (that is spaced away from the circuit portion) is at (formed in) the same layer as the first to third connection lines and is integrally formed with one of the first to third connection lines. Therefore, the contact electrode for electrically connecting the first signal line to the first connection line may be omitted to decrease the number of the contact electrodes in the driving unit, thereby preventing a malfunction of the driving unit caused by the corrosion of the contact electrode.

Also, an opening is formed through the second black matrix in an area corresponding to the location of the turn off (ground) voltage line. Therefore, the short-circuit between the turn off (ground) line and the second black matrix and a corrosion of the second black matrix may be prevented, thereby preventing a malfunction of the display apparatus.

Although the exemplary embodiments of the present invention have been described, it is understood that the present invention should not be limited to these exemplary embodiments but various changes and modifications can be made by one ordinary skilled in the art within the spirit and scope of the present invention as hereinafter claimed.

What is claimed is:

1. A driving unit comprising:
a circuit part comprising a plurality of driving stages, to output a driver signal based on a plurality of control signals; and
a line part comprising a first signal line, a second signal line, a first connection line electrically connecting the first signal line to the driving stages, and a second connection line electrically connecting the second signal line to the driving stages, the first and second signal lines transmitting the control signals, the first signal line and the first and second connection lines are positioned in a first layer different from a second layer comprising the second signal line.

2. The driving unit of claim 1, wherein the second signal line is situated between the first signal line and the plurality of driving stages.

3. The driving unit of claim 2, wherein the first signal line is integrally formed with the first connection line.

4. The driving unit of claim 1, wherein the second signal line comprises one of a start signal line transmitting a start signal to at least one of the plurality of driving stages, the start signal initiating an operation of the plurality of driving stages;
a first clock line transmitting a first clock signal to the plurality of driving stages; and
a second clock line transmitting a second clock signal, having a different phase from the first clock signal, to the plurality of driving stages.

5. The driving unit of claim 1, wherein the first signal line is a turn off (ground) voltage line transmitting a turn off (ground) voltage to the plurality of driving stages, and at least one of a start signal line and a first and second clock lines is between the first signal line and the plurality of driving stages.

6. The driving unit of claim 1, wherein at least one of the driving stages comprises:
an input terminal receiving a start signal or a driving signal from a previous driving stage;
a first clock terminal receiving one of a first clock signal and a second clock signal;
a second clock terminal receiving the other one of the first and second clock signals;
a turn off (ground) voltage terminal receiving a turn off (ground) voltage;
a control terminal receiving a carry signal from a next driving stage;
a carry terminal outputting a carry signal; and
an output terminal outputting a driving signal.

7. The driving unit of claim 6, wherein the at least one of the driving stages further comprises a reset terminal configured to receive the driving signal of a last driving stage.

8. The driving unit of claim 7, wherein the second signal line is a reset line applying the driving signal of the last driving stage to the plurality of driving stages.

9. The driving unit of claim 1, wherein each of the first layer and the second layer is a patterned deposited metal layer.

10. The driving unit of claim 1, wherein each of the driving stages is cascade-connected to another driving stage.

11. A display apparatus comprising:
a display panel configured to display images using gate signals and data signals; and
a gate driver configured to generate the gate signals, the gate driver including:
a plurality of driving stages each configured to output a gate signal based on a plurality of control signals, the driving stages being cascade-connected to one another; and
a first signal line, a second signal line, a first connection line electrically connecting the first signal line to the driving stages, and a second connection line electrically connecting the second signal line to the driving stages, the first signal line and the first and second connection lines are disposed at a different layer from the second signal line.

12. The display apparatus of claim 11, wherein the gate driver is formed on the display panel.

13. The display apparatus of claim 11, wherein the display panel comprises:
a first substrate having the gate driver outputting the gate signals, a plurality of gate lines receiving the gate signals, and a plurality of data lines receiving the data signals; and
a second substrate united with the first substrate.

14. The display apparatus of claim 13, wherein the gate lines are at a first layer, and the data lines are at a second layer different from the first layer, the data lines cross the gate lines, and the data lines are insulated from the gate lines.

15. The display apparatus of claim 14, wherein the second signal line is at the first layer, and the first signal line and the first and second connection lines are at the second layer.

16. The display apparatus of claim 15, wherein each of the first and second connection lines comprises a triple layered structure having a molybdenum tungsten sub-layer, an aluminum neodymium sub-layer and a molybdenum tungsten sub-layer.

17. The display apparatus of claim 15, wherein the first signal line is integrally formed with the first connection line.

18. The display apparatus of claim 14, wherein the first signal line and the first and second connection lines are at the first layer, and the second signal line is at the second layer.

19. The display apparatus of claim 13, wherein the display panel further comprises:
a liquid crystal layer formed between the first and second substrates; and
a sealant between the first and second substrates to unite the first substrate with the second substrate, the sealant partially overlapping the gate driver formed on the first substrate.

20. The display apparatus of claim 11, wherein the second signal line comprises one of
a start signal line a start signal to the gate driver, the start signal initiating an operation of the gate driver;
a first clock line a first clock signal to the gate driver; and
a second clock line a second clock signal to the gate driver, the second clock signal having a different phase from the first clock signal.

21. The display apparatus of claim 20, wherein the first signal line is a turn off (ground) voltage line transmitting a turn off (ground) voltage to the gate driver, and the start signal line and the first and second clock lines are between the first signal line and the gate driver.

22. A display apparatus comprising:
an array substrate comprising:
a first substrate divided into a display area, and a peripheral area adjacent to the display area;
a driver on the first substrate within the peripheral area, the driver configured to output a driver signal; and
a pixel array on the first substrate within the display area, the pixel array configured to receive the driver signal from the driver, and a second substrate, and a black matrix formed upon the second substrate to block light, the black matrix having an opening formed in the peripheral area.

23. The display apparatus of claim 22, wherein the driver comprises:
a circuit part comprising a plurality of driving stages configured to output a driver signal based, each of the driving stages being cascade-connected to one another; and
a line part comprising a first signal line and a second signal line to transmit control signals to the driver, the first signal line being positioned on a different layer from the second signal line.

24. The display apparatus of claim 23, wherein the second signal line is formed upon the first substrate, and the first signal line is formed upon an insulating layer that is formed upon the first substrate.

25. The display apparatus of claim 22, wherein the opening corresponds with the location of the first signal line, and the opening has a width greater than or substantially a same width as the first signal line.

26. The display apparatus of claim 22, wherein the black matrix comprises a metal material.

27. The display apparatus of claim 22, wherein a common electrode is formed upon the black matrix and the second substrate.

28. The display apparatus of claim 22, wherein the driver and the pixel array are formed on the first substrate by a thin film deposition process.

29. The display apparatus of claim 22, further comprising:
a liquid crystal layer between the array substrate and the second substrate; and
a sealant between the array substrate and the second substrate to unite the array substrate with the second substrate.

30. The display apparatus of claim 29, wherein the sealant partially covers at least a portion of the driver formed upon the first substrate.

31. The display apparatus of claim 29, wherein the sealant is situated between the first signal line and the opening.
